(19) United States
(12) Patent Application Publication
(10) Pub. No.: US 2022/0071029 A1
(43) Pub. Date: Mar. 3, 2022

(54) Electronic Control Unit

(71) Applicant: Hitachi Astemo, Ltd., Hitachinaka-shi, Ibaraki (JP)

(72) Inventors: Ryo AKIBA, Hitachinaka-shi, Ibaraki (JP); Yoshio KAWAI, Hitachinaka-shi, Ibaraki (JP)

(21) Appl. No.: 17/413,722

(22) PCT Filed: Dec. 19, 2019
(86) PCT No.: PCT/JP2019/049748

§ 371 Date: Jun. 14, 2021

(30) Foreign Application Priority Data
Jan. 17, 2019 (JP) 2019-005668

(51) Int. Cl. H05K 5/02; H05K 5/04; H05K 5/00

(52) U.S. Cl. CPC H05K 5/0213; B60R 16/0239; H05K 5/0026; H05K 5/04

(57) ABSTRACT

Provided is an electronic control unit that can be used even in a mounting environment causing severe salt damage. In order to achieve the above-described object, in an electronic control unit according to the present invention, a minimum distance between a wall and a respiratory filter is set to be 3 mm or more.

### TECHNICAL FIELD

The present invention relates to an electronic control unit.

### BACKGROUND ART

In recent years, automobiles have become highly improved in functions, such as electric motorization and autonomous driving, but all of the upgraded functions cannot be passed on to a vehicle price in order to secure market competitiveness, and low-cost competition for each constituent part, including an electronic control unit, has increasingly intensified.

Under this circumstance, the electronic control unit has been developed for proximity to and mechanical integration with an object to be controlled, such as an engine, a transmission, or a motor, for the purpose of reducing harnesses and connectors, and there is a need for an inexpensive electronic control unit capable of coping with a harsh temperature and vibration environment, for example, in an engine compartment.

When the electronic control unit is mounted in an environment where water splashes thereonto, for example, in the engine compartment, it is necessary to make the electronic control unit water-proof and vibration-proof. However, if the inside of the electronic control unit is completely airtight, there is concern that a case or a seal portion formed by a waterproof adhesive or the like may be damaged due to a pressure difference occurring between the inside and the outside of the electronic control unit resulting from a temperature chance. In addition, there is concern that the electronic control unit may act as a pump, and water may be drawn into the electronic control from the harness connected to the connector, which may cause a short circuit between electronic components. Therefore, it is necessary to arrange a “respiratory filter” to keep a pressure between the inside and the outside of the electronic control unit uniform. It is generally known that the respiratory filter has a structure in which an O-ring is disposed on a housing to which a filter membrane regulating a pressure difference is fixed, so that the O-ring is crushed at its mounted position between the case and the housing, thereby making the inside of the electronic control unit water-proof and vibration-proof.

Meanwhile, in order to mount the electronic control unit in a harsh temperature and vibration environment, for example, in an engine compartment, a metal material such as die-cast aluminum is generally used for the case for the purpose of securing vibration resistance and dissipating heat from the electronic components. Therefore, it is necessary to mount the respiratory filter in the die-cast aluminum case. However, salt water with a snow melting material or the like sprayed from the road adheres to the electronic control unit disposed in the engine compartment, and thereby, rust is generated on the metal case. If the metal case is corroded by the rust, there is concern that a reaction force caused by the O-ring of the respiratory filter may be lost, and the waterproofness of the electronic control unit may be impaired.

In this regard, it is generally known, for example, as in PTL 1, that a wall is provided around the respiratory filter to make it difficult for liquid to get to the respiratory filter.

### CITATION LIST

### Patent Literature

PTL 1: JP 2010-12842 A

### SUMMARY OF INVENTION

### Technical Problem

The liquid targeted by PTL 1 is high-pressure water used, for example, when washing a vehicle. According to PTL 1, a wall is provided for the purpose of preventing the high-pressure water from directly hitting a respiratory filter and invading into an electronic control unit. Thus, the wall is designed to have a height at the approximately same level as the respiratory filter, while a distance between the respiratory filter and the wall is as short as possible, thereby preventing the high-pressure water from being scattered linearly on a side portion of the respiratory filter. However, saltwater sprayed from the road may be scattered linearly, but may also be scattered in a mist type and invade even into the narrow gap between the respiratory filter and the wall. Further, the smaller the distance between the respiratory filter and the wall, the lower the drainability of the salt water. When a salt water pool is generated resulting therefrom, electrons in a metal case move and corrosion occurs. Therefore, the structure according to PTL 1 still has an issue requiring study for improving salt damage resistance.

An object of the present invention is to achieve an electronic control unit that can be used even in a mounting environment causing severe salt damage.

### Solution to Problem

In order to achieve the above-described object, in an electronic control unit according to the present invention, a minimum distance between a wall and a respiratory filter is set to be 3 mm or more.

### Advantageous Effects of Invention

According to the present invention, it is possible to achieve an electronic control unit that can be used even in a mounting environment causing severe salt damage.

### BRIEF DESCRIPTION OF DRAWINGS

FIG. 1 is a perspective view of an electronic control unit according to a first embodiment of the present invention.

FIG. 2 is an exploded view of the electronic control unit according to the first embodiment of the present invention.

FIG. 3 is a front view of the electronic control unit according to the first embodiment of the present invention.

FIG. 4 is an enlarged front view of the electronic control unit according to the first embodiment of the present invention.

FIG. 5 is a cross-sectional view of the electronic control unit according to the first embodiment of the present invention.

FIG. 6 is an enlarged cross-sectional view of the electronic control unit according to the first embodiment of the present invention.

FIG. 7 is a contact angle and a surface tension when salt water is dropped on a cover.

FIG. 8 is a perspective view of an electronic control unit according to a second embodiment of the present invention.

FIG. 9 is a cross-sectional view of the electronic control unit according to the second embodiment of the present invention.

FIG. 10 is an enlarged cross-sectional view of the electronic control unit according to the second embodiment of the present invention.

FIG. 11 is a perspective view of an electronic control unit according to a third embodiment of the present invention.

FIG. 12 is a cross-sectional view of the electronic control unit according to the third embodiment of the present invention.

FIG. 13 is an enlarged cross-sectional view of the electronic control unit according to the third embodiment of the present invention.

FIG. 14 is a front view of an electronic control unit according to a fourth embodiment of the present invention.

FIG. 15 is a cross-sectional view of the electronic control unit according to the fourth embodiment of the present invention.

FIG. 16 is an enlarged cross-sectional view of the electronic control unit according to the fourth embodiment of the present invention.

FIG. 17 is a cross-sectional view of the electronic control unit according to the fourth embodiment of the present invention when a vehicle travels.

FIG. 18 is an enlarged cross-sectional view of the electronic control unit according to the fourth embodiment of the present invention when traveling downhill.

FIG. 19 is a front view of an electronic control unit according to a fifth embodiment of the present invention.

FIG. 20 is a cross-sectional view of the electronic control unit according to the fifth embodiment of the present invention.

FIG. 21 is an enlarged cross-sectional view of the electronic control unit according to the fifth embodiment of the present invention.

FIG. 22 is a front view of an electronic control unit according to a sixth embodiment of the present invention.

FIG. 23 is a cross-sectional view of the electronic control unit according to the sixth embodiment of the present invention.

FIG. 24 is an enlarged cross-sectional view of the electronic control unit according to the sixth embodiment of the present invention.

FIG. 25 is a front view of an electronic control unit according to a seventh embodiment of the present invention.

FIG. 26 is a cross-sectional view of the electronic control unit according to the seventh embodiment of the present invention.

FIG. 27 is an enlarged cross-sectional view of the electronic control unit according to the seventh embodiment of the present invention.

FIG. 28 is a front view of an electronic control unit according to an eighth embodiment of the present invention.

FIG. 29 is a cross-sectional view of the electronic control unit according to the eighth embodiment of the present invention.

FIG. 30 is an enlarged cross-sectional view of the electronic control unit according to the eighth embodiment of the present invention.

FIG. 31 is a front view of an electronic control unit according to a ninth embodiment of the present invention.

FIG. 32 is a cross-sectional view of the electronic control unit according to the ninth embodiment of the present invention.

FIG. 33 is an enlarged cross-sectional view of the electronic control unit according to the ninth embodiment of the present invention.

FIG. 34 is a front view of an electronic control unit according to a tenth embodiment of the present invention.

FIG. 35 is a cross-sectional view of the electronic control unit according to the tenth embodiment of the present invention.

FIG. 36 is an enlarged cross-sectional view of the electronic control unit according to the tenth embodiment of the present invention.

### DESCRIPTION OF EMBODIMENTS

Hereinafter, electronic control units according to embodiments of the present invention will be described in detail with reference to the accompanying drawings.

### First Embodiment

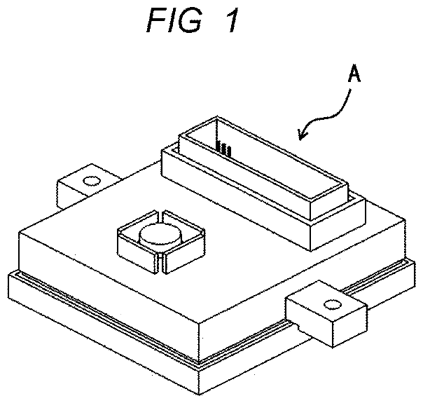

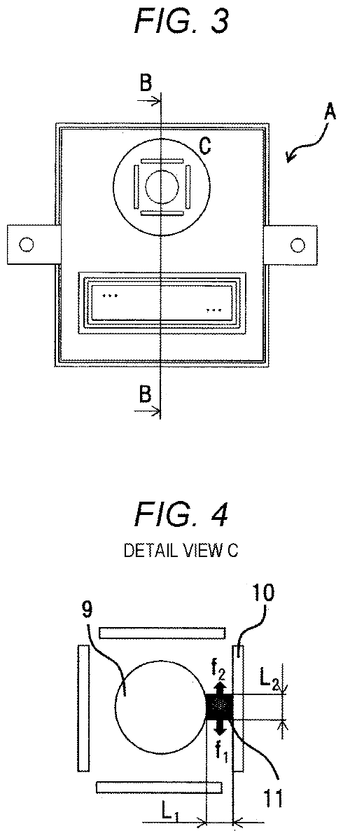

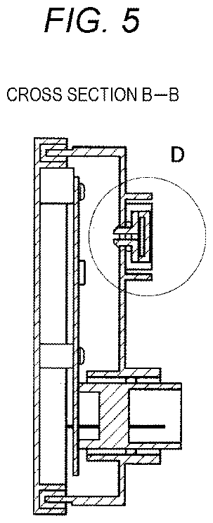

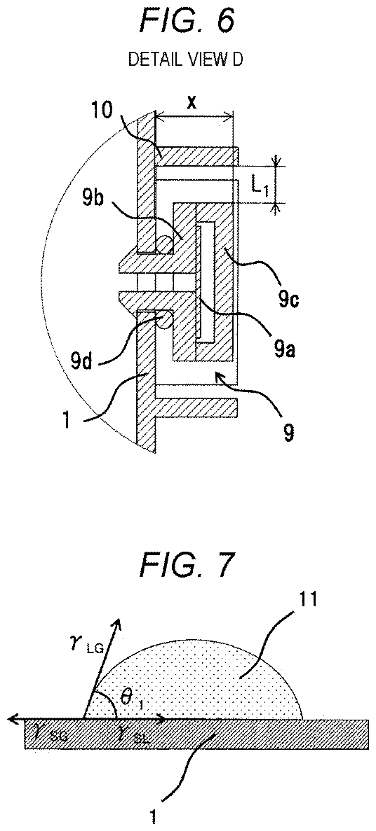

A first embodiment of the present invention will be described with reference to FIGS. 1 to 7.

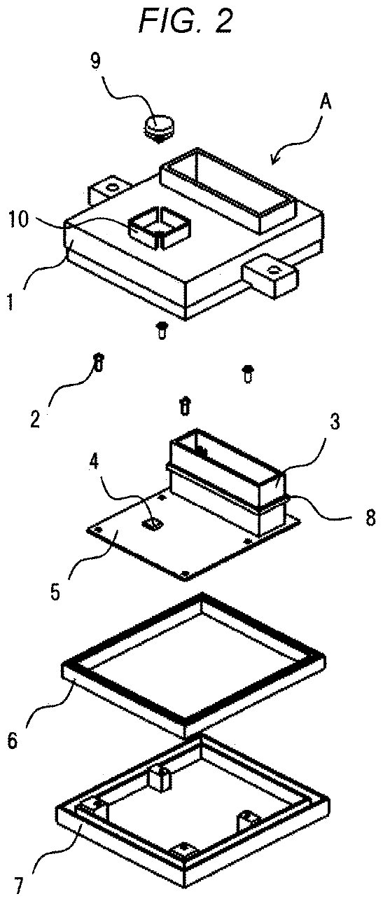

An electronic control unit A in this embodiment is mounted on, for example, an automobile and used for controlling an engine, a transmission, a brake, or the like. As illustrated in FIGS. 1 and 2, the electronic control unit A includes a circuit board 5 on which an electronic component 4 is mounted, a connector 3 mounted on the circuit board 5 to electrically connect an electric circuit formed on the circuit board 5 to an external device, a base 7 on which the circuit board 5 is accommodated, a cover 1 covering the circuit board 5 accommodated on the base 7, and a respiratory filter 9 fixed to the cover 1. In this embodiment, a case accommodating the circuit board 5 is constituted by combining the base 7 and the cover 1 together.

The circuit board 5 is held by, for example, screws 2 on the cover 1 or the base 7. In addition, a seal member (1) 6, e.g. an adhesive member, is disposed between the cover 1 and the base 7, and a seal member (2) 8, e.g. a packing member, is disposed between the cover 1 and the connector 3 to seal the inside of the electronic control unit. In addition to the electronic component 4 as illustrated, a plurality of electronic components are actually mounted on the circuit board 5. The respiratory filter 9 regulating a pressure difference between the inside and the outside of the electronic control unit A is fixed into a ventilation hole formed in the case. In this embodiment, it is shown as an example that the intake filter 9 is fixed to the cover 1. The cover 1 has a wall 10 formed around the respiratory filter 1.

The respiratory filter 9 includes, for example, a filter membrane 9a regulating a pressure difference, a housing 9b fixing the filter membrane 9a, a housing 9c covering the filter membrane 9a, and an O-ring 9d disposed between the housing 9b and the cover 1.

In order to improve the salt damage resistance of the electronic control unit A, it is necessary to prevent salt water from accumulating around the respiratory filter 9. For example, when the salt water 11 adheres at a position shown in FIG. 4, in order for the salt water 11 to be drained, a gravity f₁ of the salt water 11 caused by its weight needs to be greater than a retention force f₂ caused by surface tensions between the salt water 11 and the respiratory filter 9 and between the salt water 11 and the wall 10 (f₁>f₂).

The gravity f₁ can be expressed as f₁≅L₁L₂xρg, where L₁ is a distance between the respiratory filter 9 and the wall 10, L₂ is a length of contact between the saltwater 11 and the respiratory filter 9, x is a height of the respiratory filter 9 in a portion protruding from the electronic control unit, ρ is a density of the salt water 11, and g is a gravitational acceleration.

On the other hand, the retention force f₂ can be expressed as f₂≅2xγ_{LG} cos θ₁, where θ₁ is a contact angle of the salt water 11 when dropped on a surface of the cover 1 as in FIG. 7, γ_{SG} is a surface tension acting on the cover 1, γ_{LG} is a surface tension acting on the salt water 11, and γ_{SL} is an interfacial tension acting on an interface of the salt water 11.

Here, assuming that L₁≅L₂, L₁₂xρg>2xγ_{LG} cos θ₁, and the condition under which the gravity exceeds the surface tension is L₁>(2γ_{LG} cos θ₁/ρg)^{1/2}.

The lower the environmental temperature and the higher the salt concentration, the greater the surface tension of the salt water 11. Meanwhile, the solubility of the salt water 11 is almost constant regardless of temperature. Therefore, the surface tension is maximum, i.e. 76 mN/m, at an environmental temperature of 0° C. and a salt concentration of the salt water (saturated solution) of 26.28 wt %. Meanwhile, when the cover 1 is made of a die-cast aluminum material and the surface thereof is a cast surface having an Rz of about 50, the contact angle θ₁ is about 53° and cos θ₁≅0.6. In addition, at 26.28 wt %, the density ρ of the salt water is about 0.001 g/mm³ and the weight acceleration g is about 9800 N/g, and thus, L₁>(2γ_{LG} cos θ₁/ρg)^{1/2}=(2×75.6×0.6/(0.001×9800))^{1/2}≅3 mm.

Therefore, if the distance between the respiratory filter 9 and the wall 10 is 3 mm or more, it is possible to prevent the salt water 11 from accumulating around the respiratory filter 9. According to this embodiment, by setting the minimum distance between the wall 10 formed on the case and the respiratory filter 9 to be 3 mm or more, the salt water can be discharged by gravity, thereby suppressing accumulation of the salt water, which causes electrons to move in metal of the case. Accordingly, in this embodiment, corrosion of the case due to rust can be suppressed, thereby achieving an electronic control unit having high salt damage resistance.

### Second Embodiment

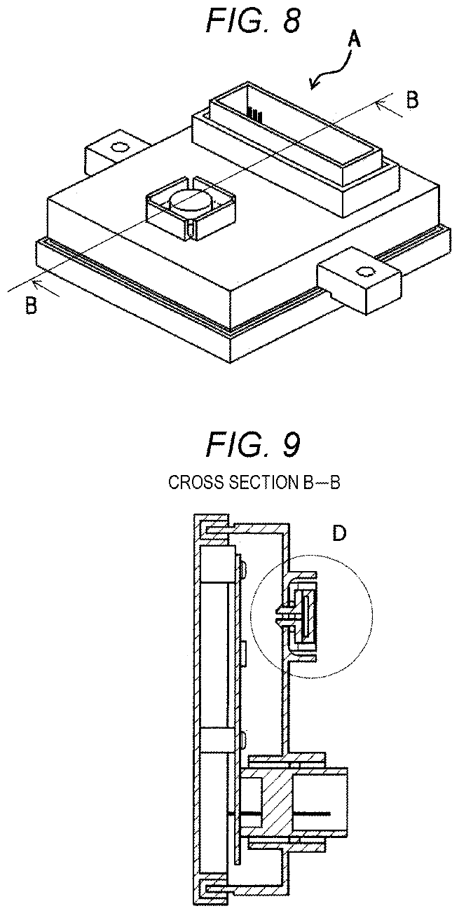

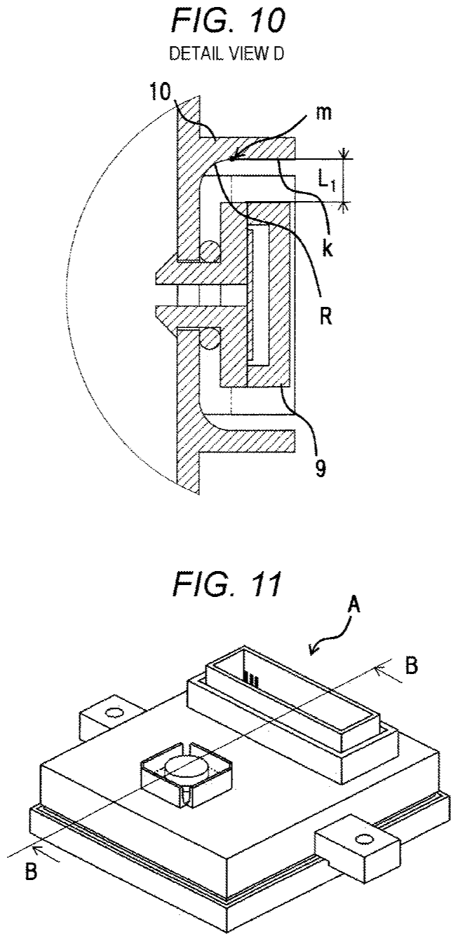

A second embodiment of the present invention will be described with reference to FIGS. 8 to 10. It should be noted that the description of the configuration that is the same as that in the first embodiment will be omitted.

In this embodiment, a curved surface R is employed to a base of the wall 10 to improve the moldability of the cover 1. Even in this case, if the shortest distance from point m, which is a joint between a surface k of the wall 10 facing the respiratory filter 9 and the curved surface R formed at the base of the wall 10, to the respiratory filter 9 is secured as 3 mm or more, drainability can be secured at the same level as that in the first embodiment, thereby achieving an electronic control unit having high salt damage resistance.

### Third Embodiment

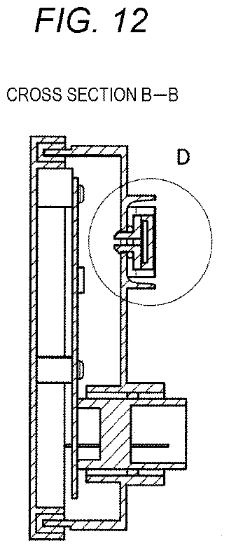

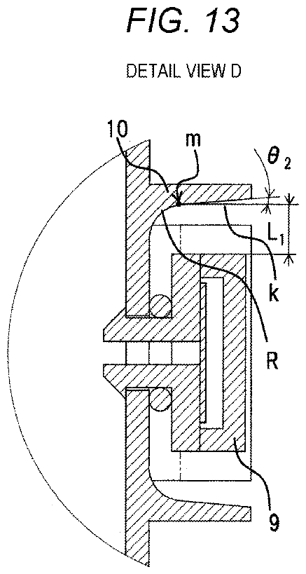

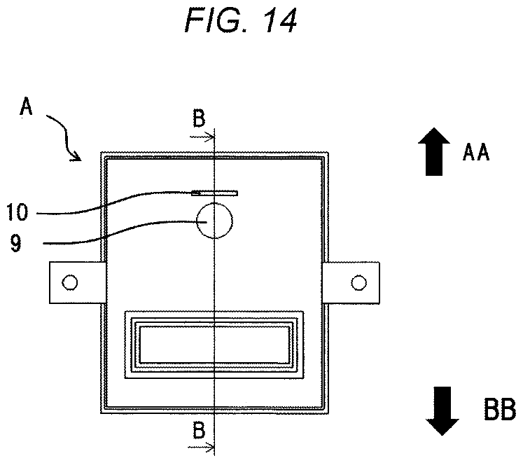

A third embodiment of the present invention will be described with reference to FIGS. 11 to 13. It should be noted that the description of the configuration that is the same as that in the first or second embodiment will be omitted.

In this embodiment, a draft angle θ₂ is employed to the surface k of the wall 10 facing the respiratory filter 9 to improve the moldability of the cover 1. Even in this case, if the shortest distance from the point m, which is the joint between the surface k and the curved surface R formed at the base of the wall 10, to the respiratory filter 9 is secured as 3 mm or more, drainability can be secured at the same level as that in the first embodiment, thereby achieving an electronic control unit having high salt damage resistance.

### Fourth Embodiment

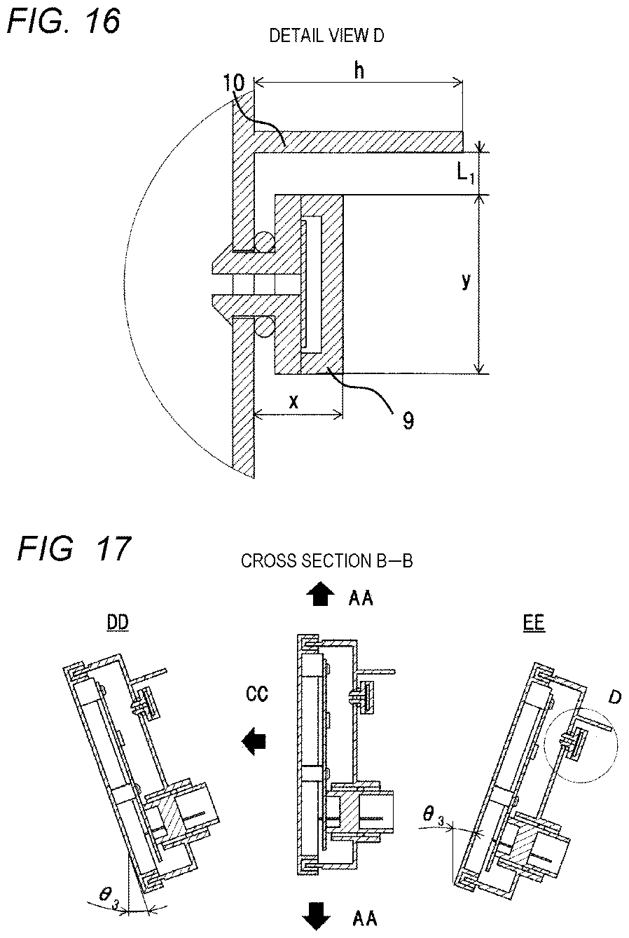

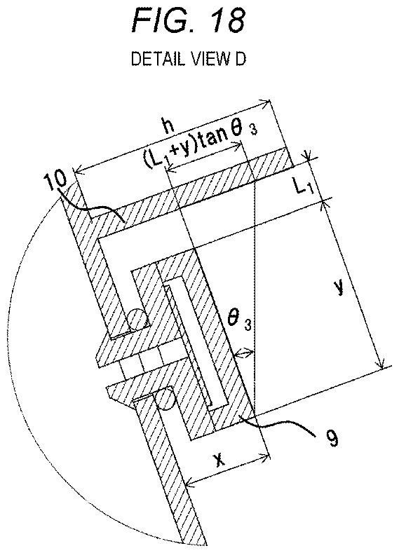

A fourth embodiment of the present invention will be described with reference to FIGS. 14 to 16. It should be noted that the description of the structure that is the same as that in the second embodiment will be omitted. It should also be noted that the description of the configuration that is the same as those in the first to third embodiments will be omitted.

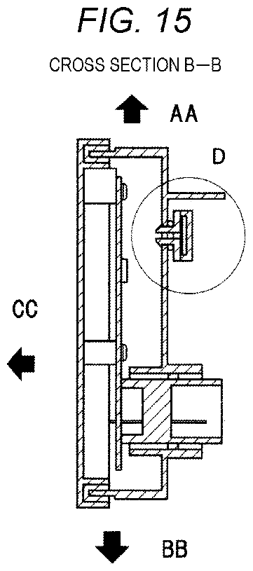

For example, as shown in FIG.15, direction AA is a direction toward an upper part mounted on the vehicle, direction BB is a direction toward a lower part mounted on the vehicle, and direction CC is a vehicle traveling direction. In this case, the wall can be provided above the respiratory filter as in FIG. 15 to prevent adhesion of the salt water sprayed up from the road and then falling from above the electronic control unit A. In contrast, if the direction AA is a direction toward a lower part mounted on the vehicle and the direction BB is a direction toward an upper part mounted on the vehicle, the salt water rolled up from the road can be prevented from being linearly scattered on the respiratory filter. As described above, since the salt damage resistance improving effect obtained by the wall 10 differs depending on its vehicle-mounted direction, the position of the wall may be changed according to the purpose.

Further, the greater h than x, the greater the effect of the wall 10, x being a height of the respiratory filter 9 protruding from the electronic control unit and h being a height of the wall 10. For example, if the direction AA is a direction toward an upper part mounted on the vehicle and the direction BB is a direction toward a lower part mounted on the vehicle, and the direction CC is a vehicle traveling direction as in FIG. 17, when the vehicle is traveling downhill with an inclination θ₃, the electronic control unit A is inclined by θ₃ in the direction CC as in case DD, and when the vehicle is traveling uphill with an inclination θ₃, the electronic control unit A is inclined by θ₃ in a direction opposite to the direction CC as in case EE. At this time, in both the cases DD and EE, by setting the height of the wall so that the respiratory filter cannot be removed from the direction AA, the saltwater can be prevented from being scattered regardless of a road surface on which the vehicle travels.

That is, the height h of the wall 10 is preferably h>x+(L₁+y) tan θ₃, where ±θ₃ is a slope of the road and y is a diameter of the respiratory filter. Since a general respiratory filter has a diameter y of ϕ17 mm and a height x of 6.5 mm, a general road has a slope of ±10°, and a minimum required distance L₁ between the respiratory filter 9 and the wall 10 is 3 mm, h>x+(L₁+y) tan θ₃=6.5+(3+17) tan 10°≅10 mm.

In this embodiment, by setting the height h of the wall 10 to be about 1.5 times or more greater than the height x of the respiratory filter 9, the salt water can be prevented from being scattered regardless of a road surface on which the vehicle travels, thereby achieving an electronic control unit having higher salt damage resistance.

The slope ±θ₃ of the road is not limited to 10°, and may be greater than 10° (e.g. 20°).

### Fifth Embodiment

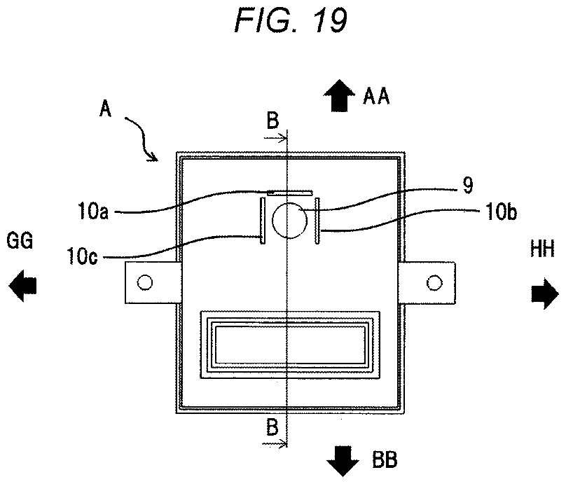

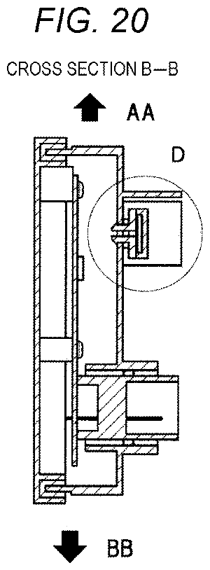

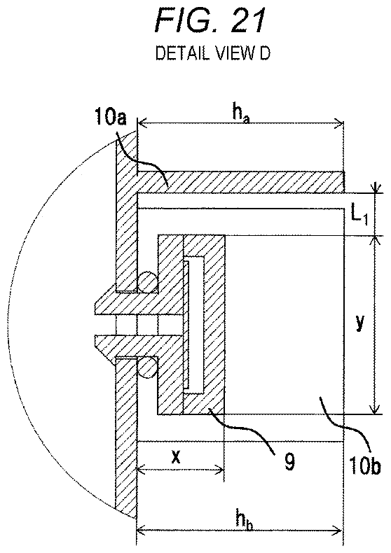

A fifth embodiment of the present invention will be described with reference to FIGS. 19 to 21.

In this embodiment as compared with the fourth embodiment, 10b and 10c formed in direction GG and direction HH, respectively, are included in addition to the wall 10a formed in the direction AA of the respiratory filter 9. When a height of the wall 10a is denoted as hₐ, a height of the wall 10b is denoted as h_{b}, and a height of the wall 10c is denoted as h_{c}, all of hₐ, h_{b}, and h_{c} are set to be greater than x+(L₁+y) tan θ₃. When a minimum distance between the wall 10a and the respiratory filter 9 is denoted as L₁ₐ, a minimum distance between the wall 10b and the respiratory filter 9 is denoted as L_{1b}, and a minimum distance between the wall 10c and the respiratory filter 9 is denoted as L_{1c}, each of L₁ₐ, L_{1b}, and L₁ₐ is set to be greater than (2γ_{LG} cos θ₁/ρg)^{1/2}. In this embodiment, since the wall 10a, the wall 10b, and the wall 10c are formed in three directions with respect to the respiratory filter 9, it is possible to suppress adhesion of salt water scattered not only in the direction AA but also in the directions GG and HH, thereby achieving an electronic control unit having higher salt damage resistance.

### Sixth Embodiment

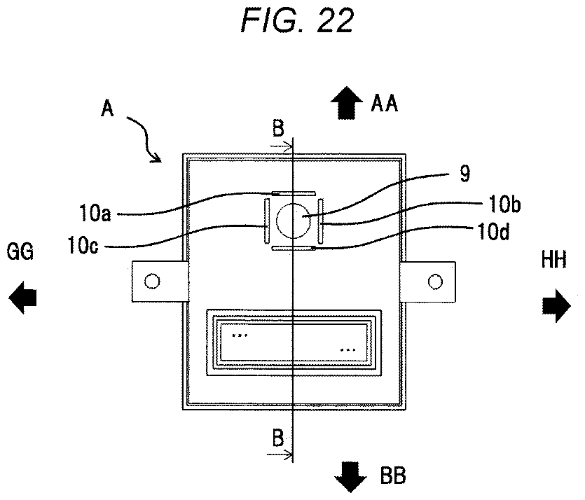

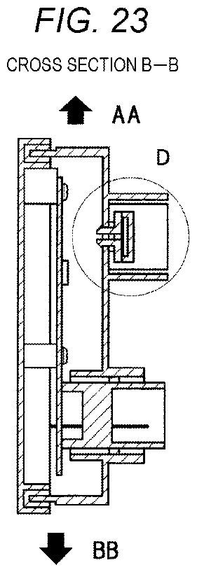

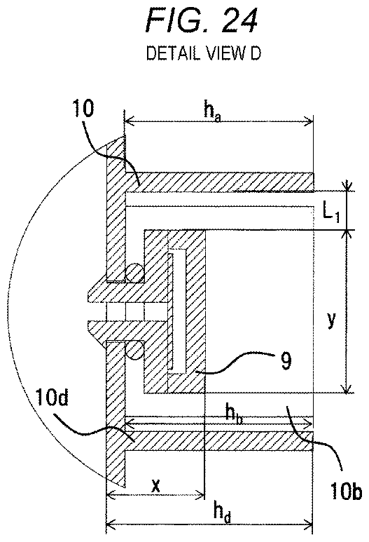

A sixth embodiment of the present invention will be described with reference to FIGS. 22 to 24.

In this embodiment as compared with the fifth embodiment, 10d formed in the direction BB is further included. When a height of the wall 10d is denoted as h_{d}, h_{d} is set to be greater than x+(L₁+y) tan θ₃. When a minimum distance between the wall 10d and the respiratory filter 9 is denoted as L_{1d}, L_{1d} is set to be greater than (2γ_{LG} cos θ₁/ρg)^{1/2}. In this embodiment, since the wall 10a, the wall 10b, the wall 10c, and the wall 10d are formed in four directions with respect to the respiratory filter 9, it is possible to suppress adhesion of salt water further scattered in the direction B, thereby achieving an electronic control unit having higher salt damage resistance.

### Seventh Embodiment

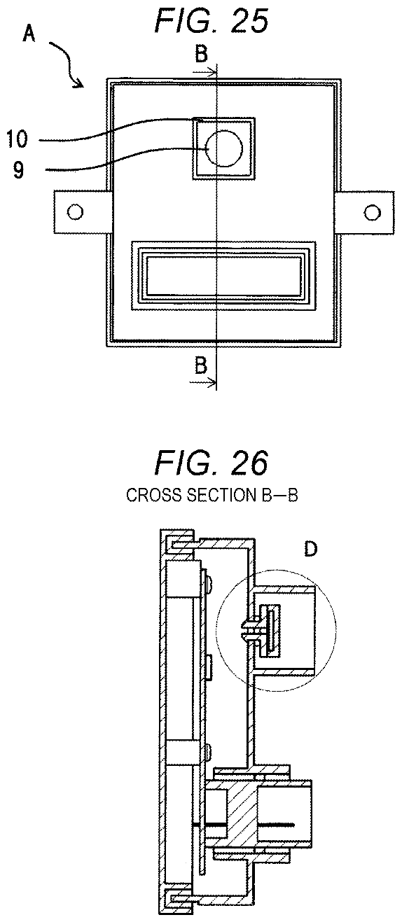

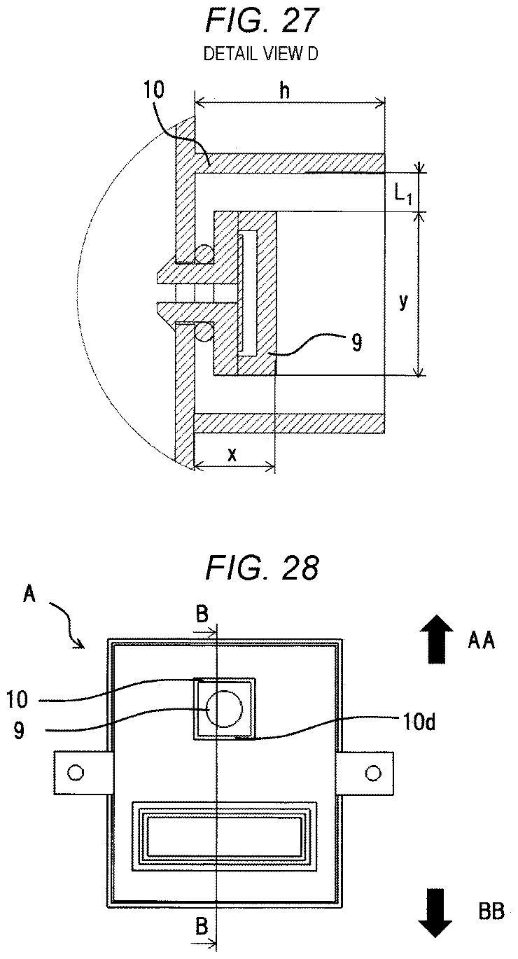

A seventh embodiment of the present invention will be described with reference to FIGS. 25 to 27.

In this embodiment as compared with the fourth embodiment, the wall 10 is formed to surround an entire circumference of the respiratory filter 9. The height h of the wall 10 is greater than x+(L₁+y) tan θ₃, and the distance L₁ between the wall 10 and the respiratory filter 9 is L₁>(2γ_{LG} cos θ₁/ρg)^{1/2}. Accordingly, it is possible to suppress adhesion of salt water scattered around the respiratory filter 9 in all directions, thereby achieving an electronic control unit having higher salt damage resistance.

### Eight Embodiment

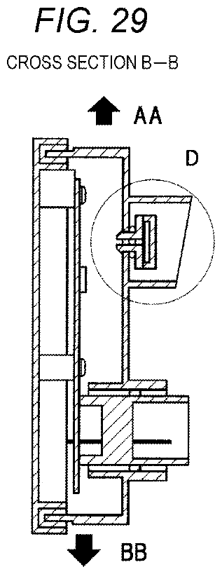

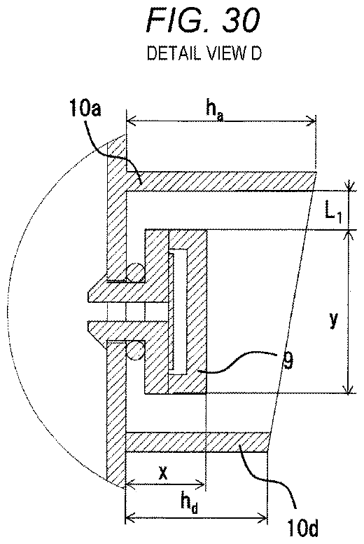

An eighth embodiment of the present invention will be described with reference to FIGS. 28 to 30.

In this embodiment as compared with the seventh embodiment, the height of the wall formed in a direction in which the saltwater is highly likely to be scattered most (e.g. the height hₐ of the wall 10a formed in the direction AA) is set to be greater than those of the walls formed in the other directions (e.g. the height h_{d} of the wall 10d formed in the direction BB). Accordingly, it is possible to achieve an electronic control unit having higher salt damage resistance.

### Ninth Embodiment

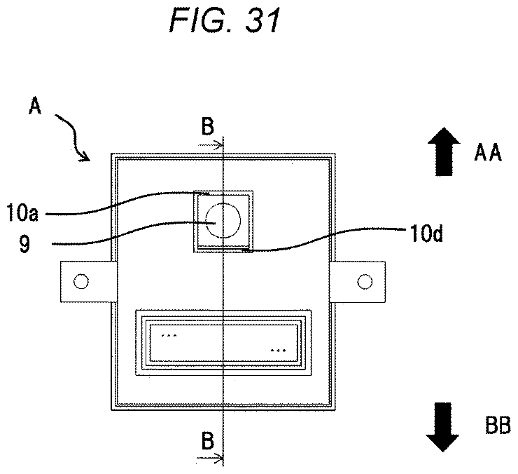

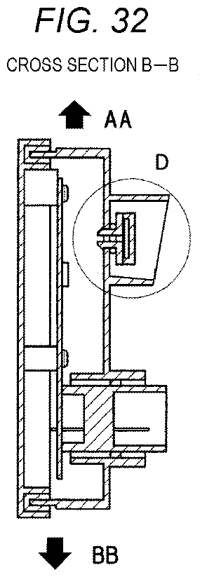

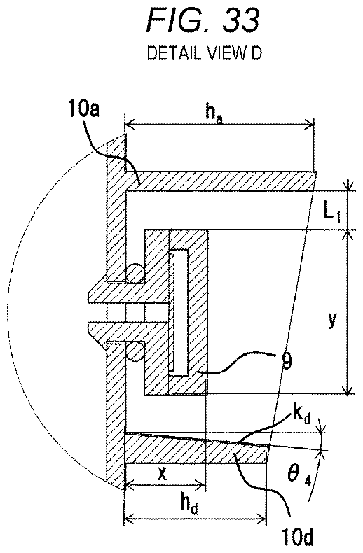

A ninth embodiment of the present invention will be described with reference to FIGS. 31 to 33.

In this embodiment as compared with the eighth embodiment, with respect to the wall below the respiratory filter 9 (e.g. the wall 10d formed in the direction BB) , an inclination θ₄ is provided on a surface k_{d} thereof facing the respiratory filter 9. According to this embodiment, by providing an inclined portion on a place where the salt water tends to be accumulated downwardly (the surface k_{d}) due to gravity, i.e. an inner wall of the wall 10d located on the lower side in the direction of gravity in the wall 10 surrounding the respiratory filter 9 when mounted on the vehicle, it is possible to efficiently discharge the salt water by virtue of gravity, thereby achieving an electronic control unit having high salt damage resistance.

### Tenth Embodiment

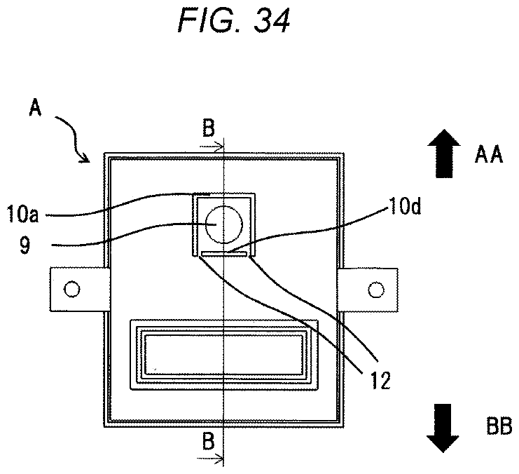

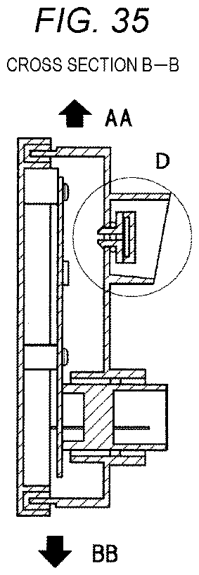

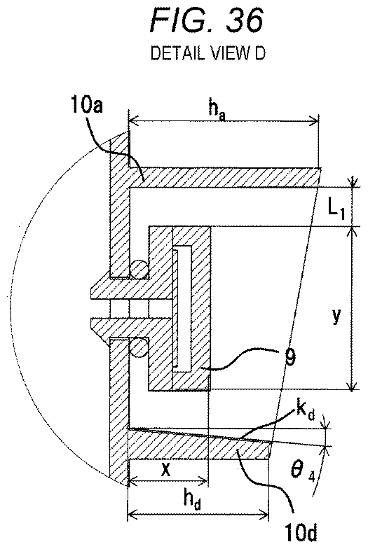

A tenth embodiment of the present invention will be described with reference to FIGS. 34 to 36.

In this embodiment as compared with the ninth embodiment, a notch 12 is provided in the wall below the respiratory filter 9 (e.g. the wall 10d formed in the direction BB). Accordingly, the drainablility of the salt water adhering to the surface k_{d} can be further improved as compared with that in the ninth embodiment, thereby achieving an electronic control unit having high salt damage resistance.

### REFERENCE SIGNS LIST

A electronic control unit
1 cover
2 screw (for fixing board)
3 connector
4 electronic component
5 circuit board
6 seal member (1)
7 base
8 seal member (2)
9 respiratory filter
10 wall
10a wall in direction AA
10b wall in direction HH
10c wall in direction GG
10d wall in direction BB
11 salt water
12 notch
L₁ distance between respiratory filter and wall
L₂ length of contact between respiratory filter/wall and salt water
h height of wall
hₐ height of wall 10a
h_{b} height of wall 10b
h_{c} height of wall 10c
h_{d} height of wall 10d
θ₁ contact angle of salt water when dropped on surface of cover
γ_{SG} surface tension acting on cover
γ_{LG} surface tension acting on salt water
γ_{SL} interfacial tension acting on interface of cover
k surface of wall facing respiratory filter
k_{d} surface of wall 10d facing respiratory filter
R curved surface at base of wall
m joint between R and surface k
θ₂ inclination of surface k
x height of respiratory filter 9 protruding from electronic control unit
y diameter of respiratory filter
h height of wall
θ₃ inclination of ground when vehicle travels
θ₄ inclination of surface k_{d}

1. An electronic control unit comprising a circuit board on which an electronic component is mounted, a metal case in which the board is accommodated, and a respiratory filter fixed to the case,
wherein the case has a wall, and a minimum distance between the wall and the respiratory filter is 3 mm or more.

2. The electronic control unit according to claim 1, wherein a curved surface is formed at a base of the wall, and a minimum distance from a joint between the curved surface and a surface of the wall facing the respiratory filter to the respiratory filter is 3 mm or more.

3. The electronic control unit according to claim 1, wherein the surface of the wall facing the respiratory filter has an inclination.

4. The electronic control unit according to claim 1, wherein the wall has a height that is 1.5 times or more greater than a height of the respiratory filter protruding from the case.

5. The electronic control unit according to claim 1, wherein the wall is formed to surround an entire circumference of the respiratory filter.

6. The electronic control unit according to claim 5, wherein the wall has a non-uniform height.

7. The electronic control unit according to claim 5, wherein the wall has a notch in at least a portion thereof.

8. An electronic control unit comprising a circuit board on which an electronic component is mounted, a metal case in which the board is accommodated, and a respiratory filter fixed to the case,
wherein the case has a wall, and
a minimum distance between the respiratory filter and the wall is (0.2γ_{LG} cos θ)^{1/2} or more, where θ is a contact angle of salt water when dropped and γ_{LG} is a surface tension acting on the salt water.

9. The electronic control unit according to claim 8, wherein the wall has a height of x+(L+y) cos 10° or more, where L is a distance between the respiratory filter and the wall, x is a height of the respiratory filter protruding beyond the case, and y is a diameter of the respiratory filter.

10. The electronic control unit according to claim 9, wherein the wall has a height of x+(L+y) cos 20° or more, where L is a distance between the respiratory filter and the wall, x is a height of the respiratory filter protruding beyond the case, and y is a diameter of the respiratory filter.

11. The electronic control unit according to claim 8, wherein the wall is formed to surround an entire circumference of the respiratory filter.

12. The electronic control unit according to claim 8, wherein the wall includes a plurality of walls.

13. The electronic control unit according to claim 1, wherein the wall includes a plurality of walls.
